(19) United States
(12) Patent Application Publication
(10) Pub. No.: US 2016/0014912 A1
(43) Pub. Date: Jan. 14, 2016

(54) FLEXIBLE DISPLAY DEVICE AND METHOD FOR PRODUCING THE SAME

(71) Applicant: EverDisplay Optronics (Shanghai) Limited, Shanghai (CN)

(72) Inventor: PingI SHIH, Shanghai (CN)

(21) Appl. No.: 14/527,270

(22) Filed: Oct. 29, 2014

(30) Foreign Application Priority Data
Jul. 10, 2014 (CN) 201410327631.4

(51) Int. Cl. H05K 5/00; H05K 3/30; H05K 1/02

(52) U.S. Cl. CPC H05K 5/0017; H05K 1/028; H05K 3/30

(57) ABSTRACT

A flexible display device and a releasing method thereof are provided. A flexible electronic assemblage including an adhesion region and an effective light emitting region is formed on a supporting carrier board. At least one flexible circuit board and at least one integrated circuit module is bonded on the adhesion region. A cutting line is provided on the supporting carrier board to divide the supporting carrier board into two parts respectively corresponding to the adhesion region and the effective light emitting region of the flexible electronic assemblage. The supporting carrier board is cut along the cutting line, and a part of the supporting carrier board under the effective light emitting region is released. The connection between the adhesion region and the supporting carrier board is reserved. Deforming of the adhesion region during the releasing process is avoided, without affecting with the bending of the flexible display device.

### CROSS REFERENCE TO RELATED APPLICATIONS

The present application claims priority under 35 U.S.C. §119 to Chinese Patent Applications No. 201410327631.4, filed on Jul. 10, 2014, the entire contents of which are incorporated herein by reference.

### TECHNICAL FIELD

The present disclosure generally relates to the field of flexible display devices, and more particularly to a flexible display device and a method for producing the same, which defines a region to be removed and a region to be preserved on a supporting carrier board.

### BACKGROUND

A flexible display, also known as a rollable display, is a bendable and deformable display device constituted of a visual flexible panel which is made of flexible material. The flexible display represents one of the most popular trends in the technical field of displays. Although flexible displays have not been put into market in large quantities, it can be expected that reel-type PDAs or e-book readers will emerge in near future, and large-format flexible wall-type displays will soon become reality. For example, all visual materials, including all kinds of books, newspapers, magazines and video files, may be presented on such displays, and viewed at anytime and anywhere. Although the currently popular MP4 players and personal digital assistants (PDA) also meet such demands, their display screens cannot be bent and folded, so texts and videos may only be displayed in a rather small area of screens, and thus the visual effect is greatly compromised. In contrast, flexible electronic displays have unparalleled advantages that they may be expanded for reading, and rolled or folded afterwards, just like newspapers, so they are conveniently portable and also have satisfying visual effects.

FIG. 1 is a top view showing a flexible electronic device according to the related art. As shown in FIG. 1, a flexible electronic assemblage 1 is located on a supporting carrier board 2 (typically a glass layer), and a flexible circuit board 3 and an integrated circuit 4 are bonded on an adhesion region 10 (the dotted region in FIG. 1) of the flexible electronic assemblage 1.

FIGS. 2A to 2C are schematic views showing structural changes of the flexible display device in a first releasing method according to the related art. Firstly, as shown in FIG. 2A, the flexible electronic assemblage 1 is formed on the supporting carrier board. Secondly, as shown in FIG. 2B, the flexible electronic assemblage 1 is released from the supporting carrier board 2. Then, as shown in FIG. 2C, the flexible circuit board 3 and an integrated circuit (referred to the reference number 4 in FIG. 1) are bonded on the adhesion region (referred to the reference number 10 in FIG. 1) of the flexible electronic assemblage 1, so as to obtain the flexible display device.

The first releasing method has a disadvantage that: during the releasing process, due to the large force needed to release the adhesion region (referred to the reference number 10 in FIG. 1), the adhesion region tends to be damaged or deformed, such that the adhesion region fails to be aligned and bonded with the flexible circuit board 3.

FIGS. 3A to 3C are schematic views showing structural changes of the flexible display device in a second releasing method according to the related art. Firstly, as shown in FIG. 3A, the supporting carrier board 2 is provided, the flexible electronic assemblage 1 is formed on the supporting carrier board, and the flexible circuit board 3 is bonded on the flexible electronic assemblage 1. Secondly, as shown in FIG. 3B, the flexible electronic assemblage 1, together with the flexible circuit board 3, is released from the supporting carrier board 2. Then, as shown in FIG. 3C, the flexible display device is obtained.

The second releasing method has a disadvantage that: the connection between the flexible circuit board 3 and the adhesion region (referred to the reference number 10 in FIG. 1) tends to be damaged during the releasing process, which results in a rather low yield rate of the final panels, and the failed panels cannot be repaired and are only directly scrapped.

The second releasing method according to the related art may also include the following steps:

providing a supporting carrier board;

forming a releasing layer on the supporting carrier board;

forming a metal layer and a buffer layer successively on the releasing layer;

forming at least one active device on the buffer layer; and

releasing the metal layer and a substrate via laser process.

Similarly, the above process also has the disadvantage of the second releasing method for the flexible display device.

In view of the above, a flexible display device and a method for producing the same are provided by the applicant, in which the damage to the connection between the flexible electronic assemblage and the flexible circuit board during the manufacturing process may be avoided.

### SUMMARY

In order to, in part, overcome the disadvantages in the related art, an object of the present disclosure is to provide a flexible display device and a method for producing the same, which may overcome the difficulties in the related art, solve the problems faced by the above-mentioned two methods by improving a releasing range of the flexible electronic assemblage, improve the yield rate of flexible panels, and simplify the producing process.

According to a first aspect of the present disclosure, a method for producing a flexible display device is provided, including: providing a flexible electronic assemblage on a supporting carrier board, wherein the flexible electronic assemblage includes an adhesion region and an effective light emitting region; bonding at least one flexible circuit board and at least one integrated circuit module on the adhesion region of the flexible electronic assemblage; providing a cutting line on the supporting carrier board to divide the supporting carrier board into two parts respectively corresponding to the adhesion region and the effective light emitting region of the flexible electronic assemblage; cutting the supporting carrier board along the cutting line; and releasing and removing a part of the supporting carrier board under the effective light emitting region.

According to a second aspect of the present disclosure, a method for producing a flexible display device is provided, including: forming a releasing layer on a supporting carrier board; providing a flexible electronic assemblage on the releasing layer, wherein the flexible electronic assemblage includes an adhesion region and an effective light emitting region; bonding at least one flexible circuit board and at least one integrated circuit module on the adhesion region of the flexible electronic assemblage; providing a cutting line on the supporting carrier board to divide the supporting carrier board into two parts respectively corresponding to the adhesion region and the effective light emitting region of the flexible electronic assemblage; cutting the supporting carrier board along the cutting line between the adhesion region and the effective light emitting region; and releasing and removing a part of the supporting carrier board under the effective light emitting region.

According to a third aspect of the present disclosure, a flexible display device is provided, including: a flexible electronic assemblage including a lower surface, and including an adhesion region and an effective light emitting region; and a flexible circuit board, configured to bond with the flexible electronic assemblage, wherein the flexible display device further includes: a partial supporting carrier board, configured to adhere to the lower surface of the flexible electronic assemblage, and be located under the adhesion region of the flexible electronic assemblage.

According to a fourth aspect of the present disclosure, a flexible display device is provided, including: a flexible electronic assemblage including an adhesion region and an effective light emitting region; a releasing layer, configured to joint with a lower surface of the flexible electronic assemblage; a flexible circuit board, configured to bond with the flexible electronic assemblage; and a partial supporting carrier board, configured to adhere to a lower surface of the releasing layer, and located under the adhesion region of the flexible electronic assemblage.

According to a fifth aspect of the present disclosure, a flexible display apparatus is provided, including the flexible display device according to a third aspect of the present disclosure.

According to a sixth aspect of the present disclosure, a flexible display apparatus is provided, including the flexible display device according to a fourth aspect of the present disclosure.

Compared with the technology in the related art, due to the above technology of the present disclosure is adopted, in the flexible display device and a method for producing the same, the flexible electronic assemblage is divided into an adhesion region and an efficient light emitting region, releasing is only performed on the efficient light emitting region, and the connection between the adhesion region and the supporting carrier board is reserved and even reinforced. Therefore, deforming of the adhesion region during the releasing process may be avoided, without affecting the bending and folding of the flexible display device. Further, the producing process of the present disclosure may be simple, and the yield rate may be improved.

### BRIEF DESCRIPTION OF THE DRAWINGS

Other characteristics, objectives and advantages of the present disclosure will become apparent from the detailed description of the non-limiting embodiments given with reference to the following accompany drawings:

FIG. 1 is a top view showing a flexible electronic device according to the related art;

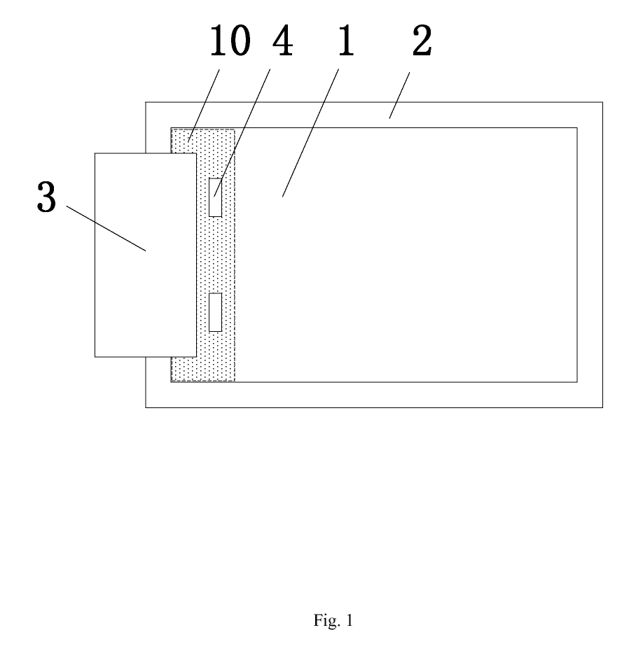

FIGS. 2A to 2C are schematic views showing structural changes of a flexible display device in a first releasing method according to the related art; and

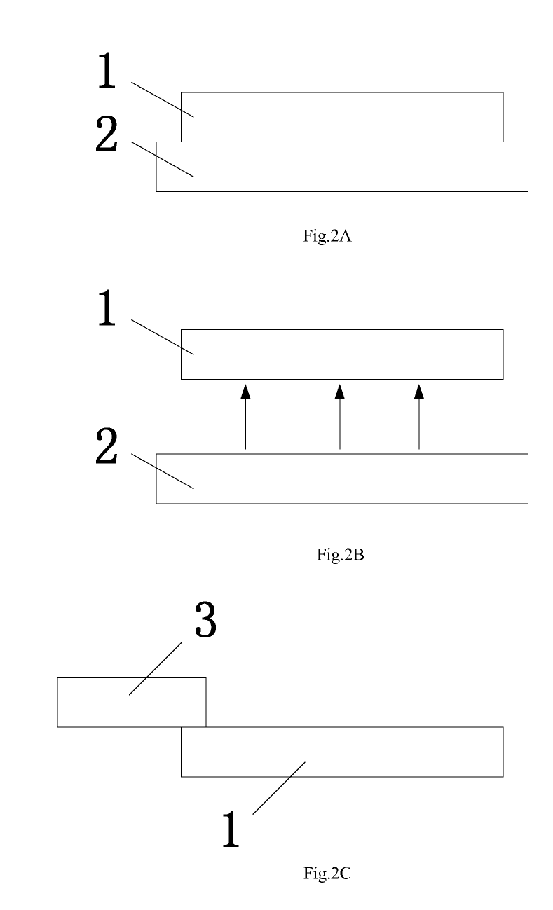

FIGS. 3A to 3C are schematic views showing structural changes of a flexible display device in a second releasing method according to the related art;

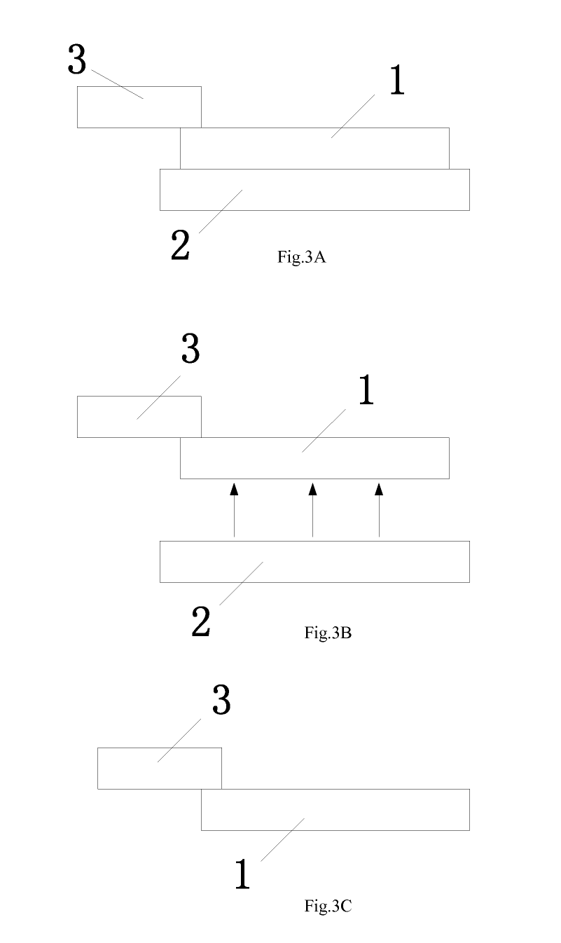

FIG. 4 is a flow chart showing a method for producing a flexible display device, according to a first embodiment of the present disclosure;

FIG. 5 is a flow chart showing a method for providing a flexible electronic assemblage in a flexible display device, according to the first embodiment of the present disclosure;

FIG. 6 is a top view showing a flexible display device, according to a specific implementation manner of the present disclosure;

FIGS. 7A to 7G are schematic views showing structural changes of a flexible display device in the first releasing method according to the first embodiment of the present disclosure;

FIG. 8 is a flow chart showing a method for producing a flexible display device, according to a second embodiment of the present disclosure;

FIGS. 9A to 9G are schematic views showing structural changes of a flexible display device in the second releasing method according to the second embodiment of the present disclosure;

FIG. 10 is a schematic structural view showing a flexible display device according to a first specific implementation manner of the present disclosure; and

FIG. 11 is a schematic structural view showing a flexible display device according to a second specific implementation manner of the present disclosure.

Reference number are described as follows:
1 flexible electronic assemblage
10 adhesion region
11 releasable flexible substrate
111 joint region
12 thin film transistor array
13 display medium layer
14 effective light emitting region
2 supporting carrier board
21 partial supporting carrier board
22 region to be removed
3 flexible circuit board
4 integrated circuit board
5 cutting line
6 tearing direction
7 releasing layer
71 adhesive region
72 releasing region

### DETAILED DESCRIPTION

It should be appreciated by those skilled in the art that, modifications can be made in combination with the prior art and the above embodiments by those skilled in the art, which will not be repeated here. Such modifications do not affect the merit of the present disclosure, and will not be repeated herein.

### A First Embodiment

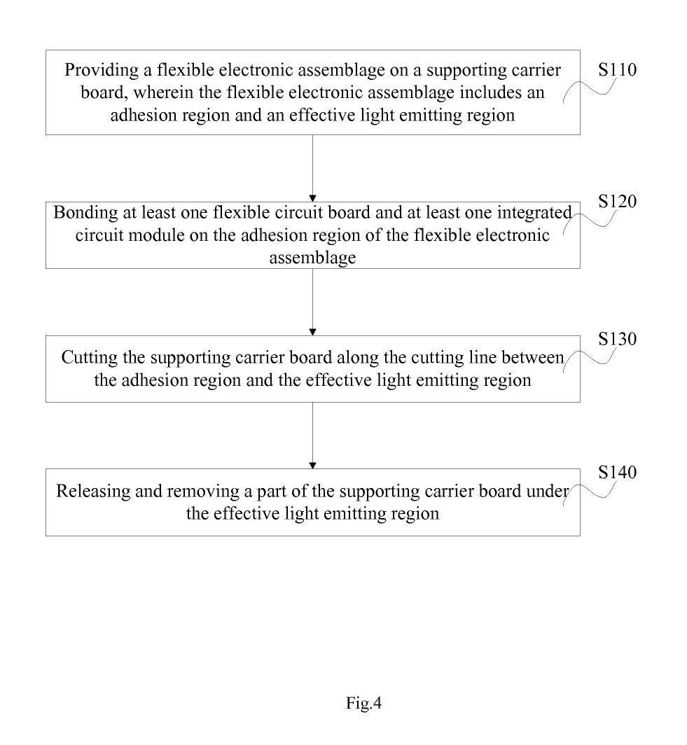

FIG. 4 is a flow chart showing a method for producing a flexible display device, according to a first embodiment of the present disclosure. As shown in FIG. 4, the method for producing the flexible display device of the present disclosure includes the following steps:

A flexible electronic assemblage is formed on a supporting carrier board, and the flexible electronic assemblage includes an adhesion region and an effective light emitting region (step S110).

At least one flexible circuit board and at least one integrated circuit module are bonded on the adhesion region of the flexible electronic assemblage (step S120).

The supporting carrier board is cut along a cutting line between the adhesion region and the effective light emitting region (step S130).

A part of the supporting carrier board under the effective light emitting region is released and removed (step S140).

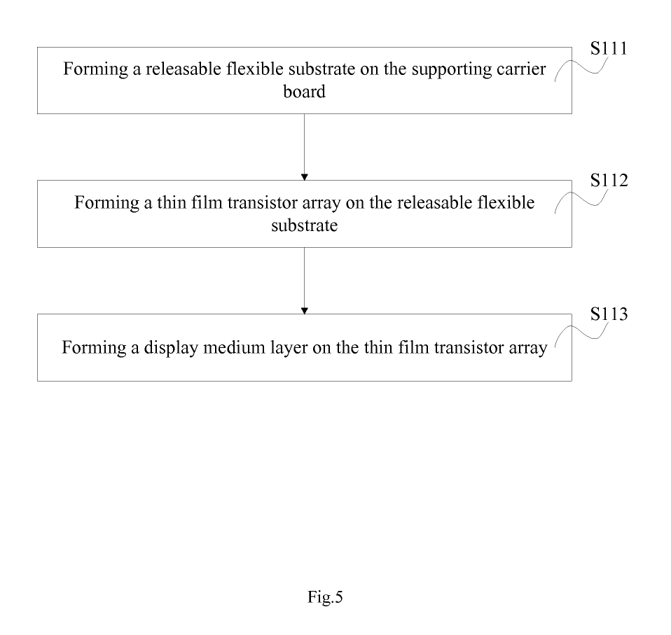

FIG. 5 is a flow chart showing a method for providing a flexible electronic assemblage in a flexible display device, according to the first embodiment of the present disclosure. As shown in FIG. 5, step S110 includes the followings sub steps:

A releasable flexible substrate is formed on a supporting carrier board (step S111).

A thin film transistor array is formed on the releasable flexible substrate (step S112).

A display medium layer is formed on the thin film transistor array (step S113).

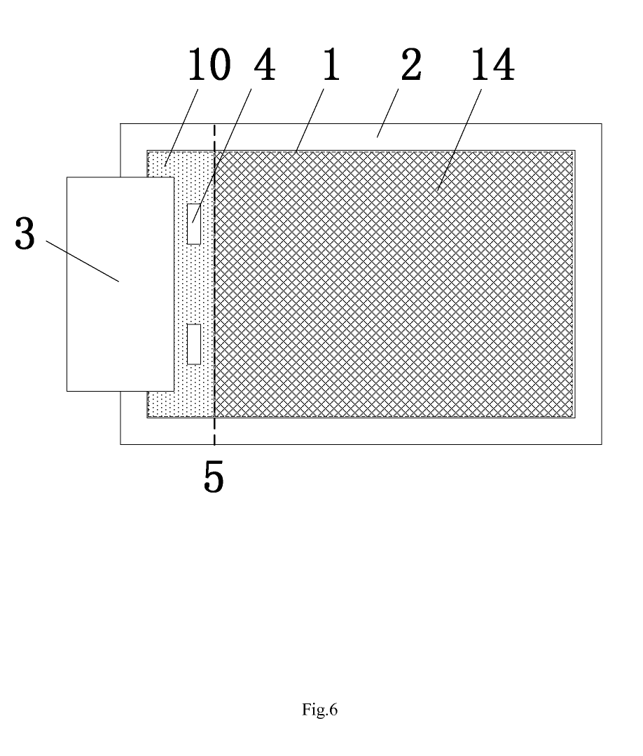

FIG. 6 is a top view showing a flexible display device, according to a specific implementation manner of the present disclosure. As shown in FIG. 6, a flexible electronic assemblage 1 is formed on a supporting carrier board 2. Typically, the flexible electronic assemblage 1 may be functionally divided into two regions: an adhesion region 10 (the dotted region in FIG. 6) at one side, configured to bond a flexible circuit board 3 and an integrated circuit 4; and an effective light emitting region 14 (the grid region in FIG. 6) on the other side, configured to display contents. In the present disclosure, a cutting line 5 is provided on the supporting carrier board 2 to divide the supporting carrier board 2 into two parts respectively corresponding to the adhesion region 10 and the effective light emitting region 14 of the flexible electronic assemblage 1. During the releasing, only the part of the supporting carrier board 2 under the effective light emitting region 14 of the flexible electronic assemblage 1 is cut off and the part of the supporting carrier board 2 under the adhesion region 10 of the flexible electronic assemblage 1 is remained, so as to obtain the flexible display device of the present disclosure.

Since during the releasing, the adhesion region 10, the flexible circuit board 3 and the integrated circuit 4 are barely exposed to a stress, they do not tend to be damaged. Moreover, due to the protection by a part of the supporting carrier board 2 from below, the adhesion region 10 may not deform, and the connection between the adhesion region 10 and the flexible circuit board 3 may be secured.

Since at least one side of the flexible display device always needs to be fixed to a device during practical usage, the supporting carrier board 2 partly preserved at this side will not affect the usage, the folding and bending of the flexible display device. An area of the preserved part of the supporting carrier board 2 may be slightly larger than that of the adhesion region 10 of the flexible electronic assemblage 1, so as to fully protect the adhesion region 10 and the like.

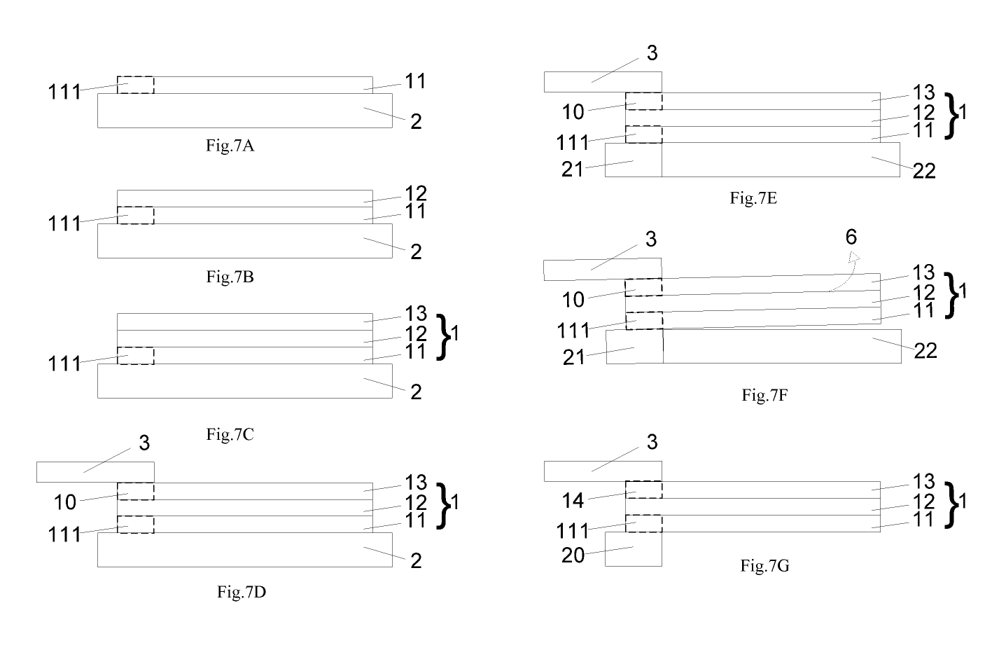

FIGS. 7A to 7G are schematic views showing structural changes of a flexible display device in the first releasing method according to the first embodiment of the present disclosure.

Referring to FIG. 7A, at step S111 shown in FIG. 5, a supporting carrier board 2 is provided. A material of the supporting carrier board 2 may be glass, metal, semiconductor or other common supporting material. A flexible electronic assemblage 1 (referred to the reference number 1 shown in FIG. 7A) is form on an upper surface of the supporting carrier board 2. The flexible electronic assemblage 1 includes a releasable flexible substrate 11, a thin film transistor array (referred to the reference number 12 shown in FIG. 7B) and a display medium layer (referred to the reference number 13 shown in FIG. 7C). Firstly, the releasable flexible substrate 11 is formed on the supporting carrier board 2. A material of the releasable flexible substrate 11 is polyimide. A joint region 111 which corresponds to an adhesion region 10 (referred to the reference number 10 shown in FIG. 6) bonding the flexible electronic assemblage 1 and a flexible circuit board (referred to the reference number 3 shown in FIG. 7C) at subsequent process steps, is defined on the releasable flexible substrate 11. The joint region 111 is heated with iron branding, a temperature range of the heating is from 200 centigrade degree to 60 centigrade degree, and a time range of the heating is from 1 second to 1 hour. Laser or plasma heating may also be used to heat this region. After the heating process, a releasing force range between the supporting carrier board and the joint region on the releasable flexible substrate that corresponds to the adhesion region is greater than 200 g. It can be seen, by heating the joint region 111, the joint region 111 is deprived of releasability such that the joint region 111 is closely adhesive to the supporting carrier board 2. Meanwhile, the rest part of the releasable flexible substrate 11 remains releasable.

Referring to FIG. 7B, at step S112 shown in FIG. 5, the thin film transistor array 12 is formed subsequently layer by layer on the releasable flexible substrate 11.

Referring to FIG. 7C, at step S113 shown in FIG. 5, the display medium player 13 is formed on the thin film transistor array 12, to complete the flexible electronic assemblage 1. The display medium player 13 may be a film layer having a displaying ability, such as a liquid crystal layer, an organic light emitting layer, an electroluminescent layer, an electronic ink layer, a cholesteric liquid crystal layer and the like, which is not limited thereto.

Referring to FIG. 7D, at step S120 shown in FIG. 4, after the flexible electronic assemblage 1 is completed, the flexible circuit board 3 and an integrated circuit module (not shown in the Figures) are bonded on the flexible electronic assemblage 1. Contact holes are formed in the thin film transistor array 12 and the display medium player 13, and electrodes are formed therein. Subsequently the flexible circuit board 3 is pressed to penetrate though respective layers to reach preset wiring positions. The region where the flexible circuit board 3 or the integrated circuit module is connected to the flexible electronic assemblage 1 is the adhesion region 10.

Referring to FIG. 7E, at step S130 shown in FIG. 4, a cutting line (referred to the reference number 5 shown in FIG. 6) is provided on a lower surface of the supporting carrier board 2 to divide the supporting carrier board 2 into two rectangles, i.e. a partial supporting carrier board 21 and a region to be removed 22. A position and a size of the partial supporting carrier board 21 correspond to those of the adhesion region 10 respectively, and a position and a size of the region to be removed 22 correspond to those of the effective light emitting region (referred to the reference number 14 shown in FIG. 6) respectively. The cutting manner of the supporting carrier board 2 depends on the setting of the cutting line. A shape of the cutting line may be a straight, a curve, a box, a polygon, a circle or an ellipse and the like, as needed in the process. For example, the cutting line is a straight line to directly divide the supporting carrier board 2 into two rectangular regions. This is the simplest process, and is beneficial for the releasing. By modifying the track of the cutting line 5, the shapes of the partial supporting carrier board 21 and a region to be removed 22 may be changed, which still falls within the protective scope of the present disclosure.

Referring to FIG. 7F, at step S140 shown in FIG. 4, the region to be removed 22 of the supporting carrier board 2 is released along the cutting line. A simple way is to tear upward to separate the flexible electronic assemblage 1 and the region to be removed 22 of the supporting carrier board 2 along a tearing direction 6.

Referring to FIG. 7G, at a final step, after the region to be removed 22 is released, and the flexible display device of the present disclosure is obtained.

In this embodiment, by reinforcing the adhesiveness between the corresponding adhesion region of the flexible electronic assemblage 1 and the supporting carrier board 2, and further integrating the flexible electronic assemblage 1 and the partial supporting carrier board 21, damage to the adhesion region 10 by the releasing process may be effectively avoided, and the bonding part between the adhesion region 10 and the flexible circuit board 3 may be protected from deforming.

### A Second Embodiment

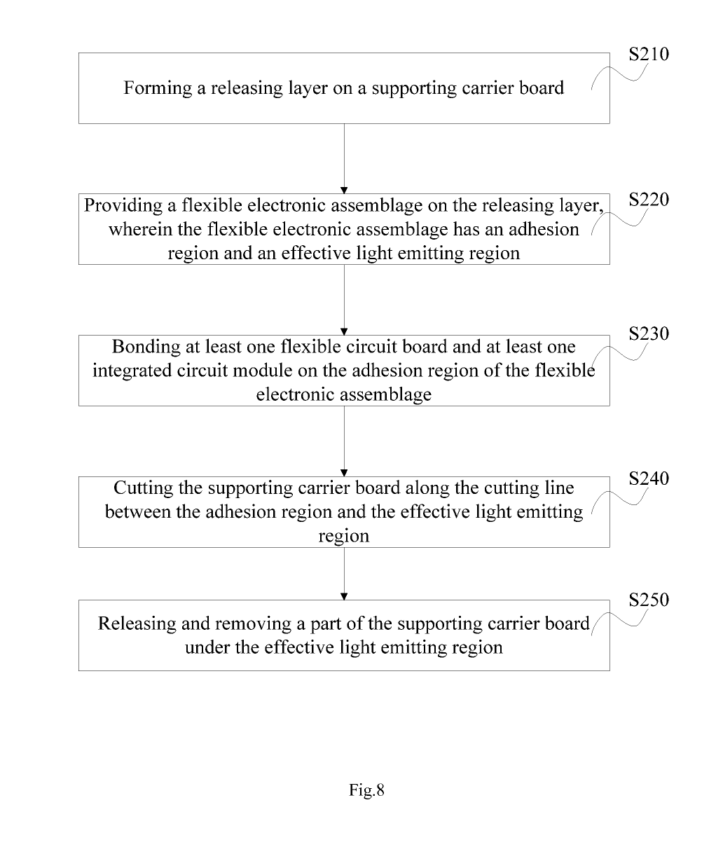

FIG. 8 is a flow chart showing a method for producing a flexible display device, according to a second embodiment of the present disclosure. As shown in FIG. 8, the method for producing the flexible display device according to the present disclosure includes the following steps:

A releasing layer is formed on a supporting carrier board (step S210).

A flexible electronic assemblage is formed on the releasing layer, and the flexible electronic assemblage includes an adhesion region and an effective light emitting region (step S220).

At least one flexible circuit board and at least one integrated circuit module are bonded on the adhesion region of the flexible electronic assemblage (step S230).

The supporting carrier board is cut along a cutting line between the adhesion region and the effective light emitting region (step S240).

The part of the supporting carrier board under the effective light emitting region is released and removed (step S250).

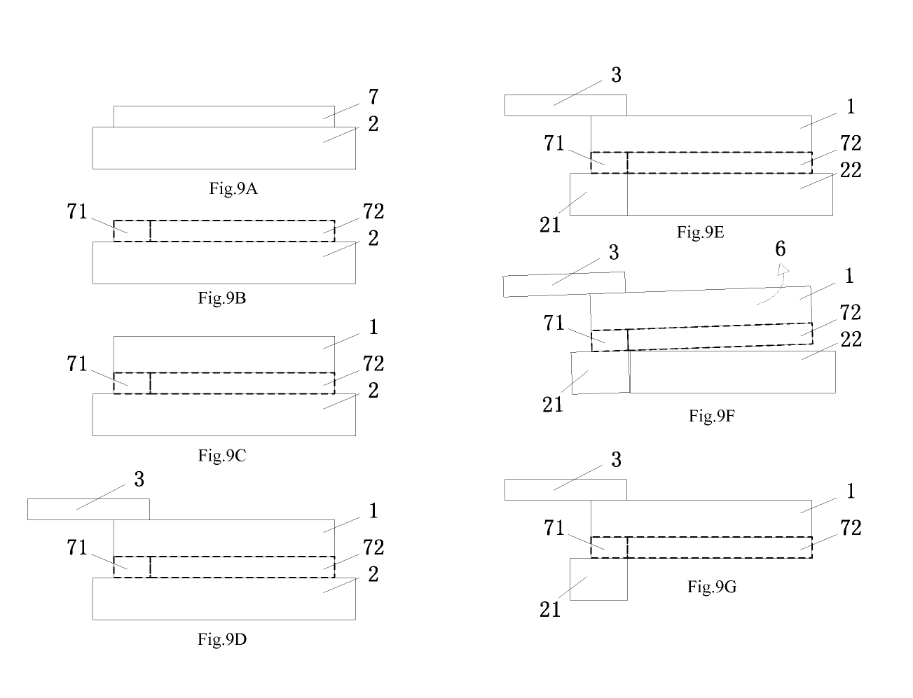

FIGS. 9A to 9C are schematic views showing structural changes of a flexible display device in the second releasing method according to the second embodiment of the present disclosure.

Referring to FIG. 9A, at step S210 shown in FIG. 8, a releasing layer 7 is formed on a supporting carrier board 2. A material of the supporting carrier board 2 is glass, metal, semiconductor or other common supporting material. A material of the releasing layer 7 is parylene.

Referring to FIG. 9B, a joint region on the releasing layer 7, which corresponds to the adhesion region (referred to the reference number 10 shown in FIG. 6) on the flexible electronic assemblage 1 at subsequent process steps, is modified to an adhesive region 71 that has adhesiveness, and the unmodified part of the releasing layer forms a releasing region 72 that has no adhesiveness. The adhesive region 71 is more closely adhered to the supporting carrier board 2. The partially modification may be processed through several manners. For example, a partial exposure process using a light source is performed on the releasing layer 7 including a light-sensitive adhesive layer, such that a part of the releasing layer which is irradiated by the light source generates adhesiveness and forms the adhesive region 71, and a part of the releasing layer which is not irradiated by the light source does not have adhesiveness and forms the releasing region 72 that has no adhesiveness. Or, the partially modification process includes a partial heating process, in which the part of the releasing layer which is heated generates adhesiveness and forms an adhesive region 71, and the part of the releasing layer which is not heated does not have adhesiveness and forms the releasing region 72.

Referring to FIG. 9C, at step S220 shown in FIG. 8, the flexible electronic assemblage 1 is then formed on the releasing layer 7. The flexible electronic assemblage 1 includes a flexible substrate, a thin film transistor array and a display medium layer (referred to those shown in FIG. 7). The display medium layer may be a film layer having a displaying ability such as a liquid crystal layer, an organic light emitting layer, an electroluminescent layer, an electronic ink layer, a cholesteric liquid crystal layer and the like, which is not limited thereto.

Referring to FIG. 9D, at step S230 shown in FIG. 8, at least one flexible circuit board 3 and integrated circuit module (not shown in the Figures) are bonded on the flexible electronic assemblage 1. Contact holes are formed in the flexible electronic assemblage 1, and electrodes are formed therein. The flexible circuit board 3 is pressed to penetrate though respective layers to reach preset wiring positions. The region where the flexible circuit board 3 and the flexible electronic assemblage 1 are connected is the adhesion region 10 (referred to the reference number 10 shown in FIG. 6).

Referring to FIG. 9E, at step S240 shown in FIG. 8, a cutting line (referred to the reference number 5 shown in FIG. 6) is provided on a lower surface of the supporting carrier board 2 to divide the supporting carrier board into two rectangles, i.e. a partial supporting carrier board 21 and a region to be removed 22. A position and a size of the partial supporting carrier board 21 correspond to those of the adhesion region (referred to the reference number 10 shown in FIG. 6) respectively, and a position and a size of the region to be removed 22 correspond to those of the effective light emitting region (referred to the reference number 14 shown in FIG. 6) respectively. The cutting manner of the supporting carrier board 2 depends on the setting of the cutting line. A shape of the cutting line may be a straight, a curve, a box, a polygon, a circle or an ellipse and the like, as needed in the process. For example, the cutting line 5 is a straight line to directly divide the supporting carrier board 2 into two rectangular regions. This is the simplest process, and is beneficial for the releasing. By modifying the track of the cutting line 5, the shapes of the partial supporting carrier board 21 and a region to be removed 22 may be changed, which still falls within the protective scope of the present disclosure.

Referring to FIG. 9F, at step S250 shown in FIG. 8, the region to be removed 22 of the supporting carrier board 2 is released along the cutting line. Since the releasing region 72 on the region to be removed 22 is not adhesive, a simple way is to tear upward to separate the flexible electronic assemblage 1 and the region to be removed 22 along a tearing direction 6.

Referring to FIG. 9G, after the region to be removed 22 is removed, the flexible display device of the present disclosure is obtained (a distinct difference from the first embodiment lies in that, the flexible display device according to this embodiment has a releasing layer).

In this embodiment, by reinforcing the adhesiveness between the corresponding adhesion region of the releasing layer 7 and the supporting carrier board 2, and further integrating the flexible electronic assemblage 1 and the partial supporting carrier board 21 by the releasing layer 7, damage to the adhesion region 10 by the releasing process may effectively avoided, and the bonding part between the adhesion region 10 and the flexible circuit board 3 may be protected from deforming. Through the method according to the present disclosure, the yield rate of the products may be improved.

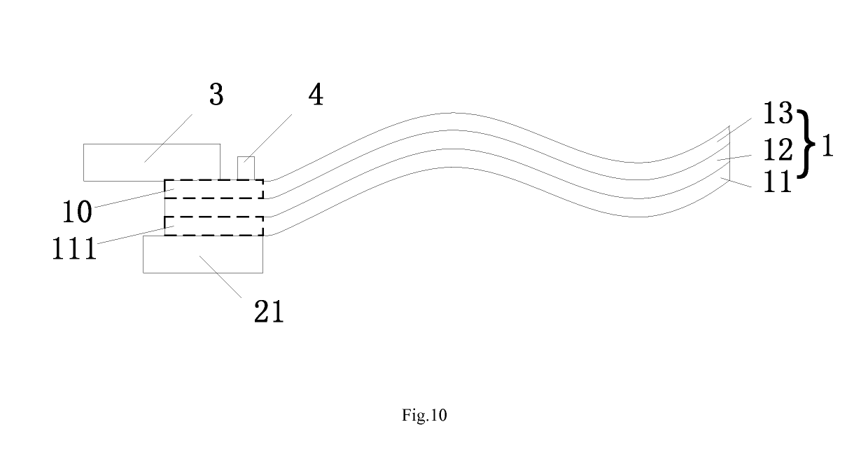

FIG. 10 is a schematic structural view showing a flexible display device according to a first specific implementation manner of the present disclosure. As shown in FIG. 10, through the series of producing steps according to the first embodiment, the flexible display device of the present disclosure includes a flexible electronic assemblage 1, a partial supporting carrier board 21, a flexible circuit board 3 and an integrated circuit 4. The flexible electronic assemblage 1 includes a releasable flexible substrate 11, a thin film transistor array 12 and a display medium player 13. An efficient light emitting region (referred to the reference number 14 shown in FIG. 6) on the flexible electronic assemblage 1 may be arbitrarily bent and folded as well as the existing flexible electronic assemblage. While the flexible circuit board 3 and the integrated circuit 4 are bonded on the adhesion region 10 of the flexible electronic assemblage 1, and the joint region 111 on the releasable flexible substrate 11 is closely adhered to the partial supporting carrier board 21. The position of the partial supporting carrier board 21 corresponds to the adhesion region 10 on the flexible electronic assemblage 1.

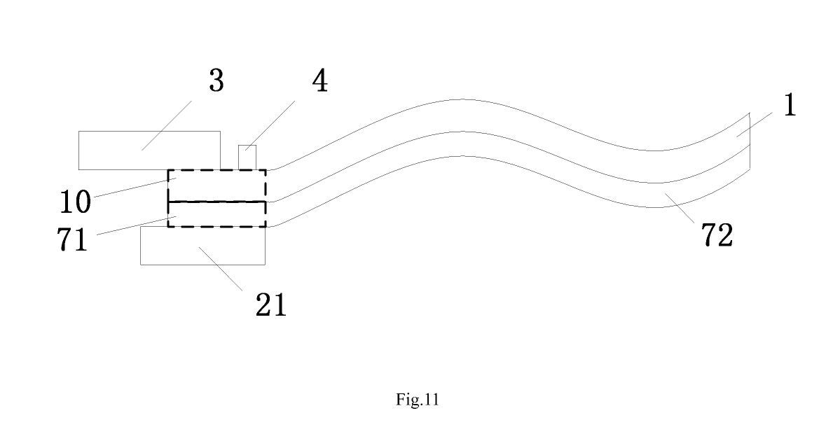

FIG. 11 is a schematic structural view showing a flexible display device according to a second specific implementation manner of the present disclosure. As shown in FIG. 11, through the series of producing steps according to the second embodiment, the flexible display device of the present disclosure includes a flexible electronic assemblage 1, a partial supporting carrier board 21, a flexible circuit board 3, a releasing layer and an integrated circuit 4. The releasing layer is provided between the flexible electronic assemblage 1 and the partial supporting carrier board 21, and includes the adhesive region 71 and the releasing region 72, and the partial supporting carrier board 21 is adhere to the adhesive region 71. An efficient light emitting region (referred to the reference number 14 shown in FIG. 6) on the flexible electronic assemblage 1 may be arbitrarily bent and folded as well as the existing flexible electronic assemblage. While the flexible circuit board 3 and the integrated circuit 4 are bonded on the adhesion region 10 of the flexible electronic assemblage 1. The position of the partial supporting carrier board 21 corresponds to the adhesion region 10 on the flexible electronic assemblage 1.

The flexible display device produced through the method according to the present disclosure has a symbolic feature that a part of the supporting carrier board (typically a glass board, a metal board or a semiconductor board) is preserved under the flexible electronic assemblage, which is different from the flexible display device produced through the method in the related art, having no any supporting carrier board under the flexible electronic assemblage. Any flexible display device with a structure that a part of the supporting carrier board is preserved under the flexible electronic assemblage falls within the protective scope of the present disclosure.

The flexible display device according to the present disclosure may be applied to various electronic devices. A display apparatus of the present disclosure is a mobile terminal which is provided with the above flexible display device. The display apparatus of the present disclosure may be a mobile phone, a tablet computer, or a digital player and the like, which includes the above flexible display device.

Accordingly, in the flexible display device and a method for producing the same, the flexible electronic assemblage is divided into an adhesion region and an efficient light emitting region, releasing is only performed on the efficient light emitting region, and the connection between the adhesion region and the supporting carrier board is reserved and even reinforced. Therefore, deforming of the adhesion region during the releasing process is avoided, without affecting the bending and folding of the flexible display device. Further, the producing process may be simple, and the yield rate may be improved.

The embodiments of the present disclosure have been described as the above. It should be appreciated that, the present disclosure is not limited to the above embodiments, and various alterations and modifications may be made within the scope of the claims by those skilled in the art, without affecting the merit of the present disclosure.

What is claimed is:

1. A method for producing a flexible display device, comprising:
providing a flexible electronic assemblage on a supporting carrier board, wherein the flexible electronic assemblage comprises an adhesion region and an effective light emitting region;
bonding at least one flexible circuit board and at least one integrated circuit module on the adhesion region of the flexible electronic assemblage;
providing a cutting line on the supporting carrier board to divide the supporting carrier board into two parts respectively corresponding to the adhesion region and the effective light emitting region of the flexible electronic assemblage;
cutting the supporting carrier board along the cutting line; and
releasing and removing a part of the supporting carrier board under the effective light emitting region.

2. The method for producing a flexible display device according to claim 1, wherein the flexible electronic assemblage is a releasable electronic assemblage.

3. The method for producing a flexible display device according to claim 2, wherein the step of forming the flexible electronic assemblage comprises:
forming a releasable flexible substrate on the supporting carrier board;
forming a thin film transistor array on the releasable flexible substrate; and
forming a display medium layer on the thin film transistor array.

4. The method for producing a flexible display device according to claim 3, wherein after the step of forming the releasable flexible substrate and before the step of forming the thin film transistor array, the method further comprises:
heating a joint region on the releasable flexible substrate, wherein the joint region corresponds to the adhesion region.

5. The method for producing a flexible display device according to claim 4, wherein the heating step is executed by laser heating, iron branding or plasma heating.

6. The method for producing a flexible display device according to claim 4, wherein a temperature range of the heating step is from 200 centigrade degree to 60 centigrade degree.

7. The method for producing a flexible display device according to claim 4, wherein a time range of the heating step is from 1 second to 1 hour.

8. The method for producing a flexible display device according to claim 3, wherein a material of the releasable flexible substrate comprises polyimide.

9. The method for producing a flexible display device according to claim 1, wherein a preserved part of the supporting carrier board completely covers the adhesion region of the flexible electronic assemblage.

10. The method for producing a flexible display device according to claim 1, wherein a shape of the cutting line is at least one of a straight, a curve, a box, a polygon, a circle and an ellipse.

11. The method for producing a flexible display device according to claim 1, wherein the supporting carrier board is selected from a group consisting of a glass carrier board, a semiconductor carrier board and a metal carrier board.

12. A method for producing a flexible display device, comprising:
forming a releasing layer on a supporting carrier board;
providing a flexible electronic assemblage on the releasing layer, wherein the flexible electronic assemblage comprises an adhesion region and an effective light emitting region;
bonding at least one flexible circuit board and at least one integrated circuit module on the adhesion region of the flexible electronic assemblage;
providing a cutting line on the supporting carrier board to divide the supporting carrier board into two parts respectively corresponding to the adhesion region and the effective light emitting region of the flexible electronic assemblage;
cutting the supporting carrier board along the cutting line between the adhesion region and the effective light emitting region; and
releasing and removing a part of the supporting carrier board under the effective light emitting region.

13. The method for producing a flexible display device according to claim 12, wherein the method further comprises a step of modifying a part of the releasing layer that corresponds to the adhesion region of the flexible electronic assemblage to an adhesive region that has adhesiveness, wherein an unmodified part of the releasing layer forms a releasing region that has no adhesiveness.

14. The method for producing a flexible display device according to claim 13, wherein the supporting carrier board and the flexible electronic assemblage are jointed via the adhesive region of the releasing layer.

15. The method for producing a flexible display device according to claim 14, wherein the releasing layer comprises a light-sensitive adhesive layer, and the modifying step comprises a partial exposure process using a light source, to make a part of the releasing layer which is irradiated by the light source generates adhesiveness and forms the adhesive region, and a part of the releasing layer which is not irradiated by the light source does not has adhesiveness and forms the releasing region.

16. The method for producing a flexible display device according to claim 14, wherein the releasing layer comprises a heat-sensitive adhesive layer, and the modifying step comprises using a partial heating process, to make a part of the releasing layer which is heated generates adhesiveness and forms the adhesive region, and a part of the releasing layer which is not heated does not has adhesiveness and forms the releasing region.

17. The method for producing a flexible display device according to claim 16, wherein the partial heating process is performed after the step of forming the releasing layer and before the step of forming the flexible electronic assemblage.

18. The method for producing a flexible display device according to claim 12, wherein a preserved part of the supporting carrier board completely covers the adhesion region of the flexible electronic assemblage.

19. The method for producing a flexible display device according to claim 12, wherein a shape of the cutting line is at least one of a straight, a curve, a box, a polygon, a circle and an ellipse.

20. The method for producing a flexible display device according to claim 12, wherein the supporting carrier board is selected from a group consisting of a glass carrier board, a semiconductor carrier board and a metal carrier board.

21. A flexible display device, comprising:
a flexible electronic assemblage comprising a lower surface, and comprising an adhesion region and an effective light emitting region; and
a flexible circuit board, configured to bond with the flexible electronic assemblage,
wherein the flexible display device further comprises:
a partial supporting carrier board, configured to adhere to the lower surface of the flexible electronic assemblage, and be located under the adhesion region of the flexible electronic assemblage.

22. The flexible display device according to claim 21, wherein the partial supporting carrier board completely covers the adhesion region of the flexible electronic assemblage.

23. The flexible display device according to claim 21, wherein a shape of the partial supporting carrier board is selected from a group consisting of a triangle, a rectangle, a polygon, a circle and an ellipse.

24. The flexible display device according to claim 23, wherein the partial supporting carrier board is selected from a group consisting of a glass carrier board, a semiconductor carrier board and a metal carrier board.

25. A flexible display device, comprising:
a flexible electronic assemblage comprising an adhesion region and an effective light emitting region;
a releasing layer, configured to joint with a lower surface of the flexible electronic assemblage;
a flexible circuit board, configured to bond with the flexible electronic assemblage; and
a partial supporting carrier board, configured to adhere to a lower surface of the releasing layer and located under the adhesion region of the flexible electronic assemblage.

26. The flexible display device according to claim 25, wherein the partial supporting carrier board completely covers the adhesion region of the flexible electronic assemblage.

27. The flexible display device according to claim 25, wherein the releasing layer completely covers the flexible electronic assemblage.

28. The flexible display device according to claim 25, wherein a shape of the partial supporting carrier board is selected from a group consisting of a triangle, a rectangle, a polygon, a circle and an ellipse.

29. The flexible display device according to claim 25, wherein the partial supporting carrier board is selected from a group consisting of a glass carrier board, a semiconductor carrier board and a metal carrier board.
